(19) United States
(12) Patent Application Publication
(10) Pub. No.: US 2018/0211852 A1
(43) Pub. Date: Jul. 26, 2018

(54) LASER PROCESSING APPARATUS

(71) Applicant: DISCO CORPORATION, Tokyo (JP)

(72) Inventors: Yuri Ban, Tokyo (JP); Yuta Yoshida, Tokyo (JP); Kentaro Odanaka, Tokyo (JP)

(21) Appl. No.: 15/878,162

(22) Filed: Jan. 23, 2018

(30) Foreign Application Priority Data
Jan. 24, 2017 (JP) 2017-010343

(51) Int. Cl. H01L 21/67; B23K 26/364; B23K 26/03; H01L 21/68; H01L 23/544; H01L 21/268; H01L 21/56; H01L 21/304; H01L 21/78

(52) U.S. Cl. CPC H01L 21/67092; B23K 26/364; B23K 26/032; H01L 21/67282; H01L 21/67126; H01L 21/681; H01L 2223/5446; H01L 21/268; H01L 21/565; H01L 21/561; H01L 21/304; H01L 21/78; H01L 23/544

(57) ABSTRACT

A laser processing apparatus includes: a chuck table that holds a packaged wafer; a laser beam applying unit that applies a pulsed laser beam to the packaged wafer; X-axis moving unit for moving the chuck table in an X-axis direction; an imaging unit that images the packaged wafer; and a control unit. The chuck table has a transparent or semi-transparent holding member and a light emitting body. The control unit includes: an imaging instruction section that causes the imaging unit to image the packaged wafer while the pulsed laser beam is being applied to the packaged wafer; and a determination section that determines the processed state of a through-groove from a picked-up image obtained according to an instruction by the imaging instruction section.

### BACKGROUND OF THE INVENTION

### Field of the Invention

The present invention relates to a method of manufacturing a packaged device.

### Description of the Related Art

As a processing method for dividing a semiconductor wafer into individual device chips, cutting by a cutting blade and ablation by applying a pulsed laser beam are known. Each of the individually divided device chips is fixed to a mother substrate or the like, wired by wires or the like, and is packaged with a molding resin, in general. However, due to a minute crack or the like in a side surface of the device chip, when the device chip is used for a long time, the crack may expand, leading to breakage of the device chip. In order to restrain such breakage of the device chip, a packaging technique of covering side surfaces of the device chip with a molding resin to thereby prevent external environmental factors from influencing the device chip has been developed (see, for example, Japanese patent Laid-open No. 2002-100709).

In the packaging technique disclosed in Japanese Patent Laid-open No. 2002-100709, first, grooves are formed along division lines (streets) on the wafer from the front side of the wafer, and a molding resin is placed to fill the grooves and cover the wafer surface. Thereafter, in the packaging technique of Japanese Patent Laid-open No. 2002-100709, the wafer is thinned from the back side until the molding resin in the grooves is exposed, to thereby divide the devices on the wafer. Finally, in the packaging technique of Japanese Patent Laid-open No. 2002-100709, the molding resin is divided from the front side of the wafer, to thereby divide the wafer into the individual device chips. In the above-mentioned packaging technique, use of ablation by applying a pulsed laser beam, instead of cutting, for dividing the wafer into the device chips has been developed. The use of ablation is beneficial because it makes it possible to make extremely narrow the cutting allowance used for division between the device chips, to design the division lines in a very thin form, and thereby to increase the number of device chips obtained per wafer.

### SUMMARY OF THE INVENTION

The ablation by application of a pulsed laser beam is a processing method in which, for forming very narrow through-grooves in the molding resin, a pulsed laser beam is scanned multiple times to gradually deepen the narrow grooves. In the ablation by application of a pulsed laser beam, the processing is conducted with a minimum number of times of scanning of the pulsed laser beam, for shortening the processing time. Therefore, when there is a part where the molding resin is abruptly thicker, the molding resin at the part cannot be removed and, hence, a through-groove cannot be formed properly, so that a blind hole state would be generated. Accordingly, in the processing method of the related art, the operator checks the wafers one by one after the ablation, and discards the region with the through-groove in a blind hole state as a defective chip. Thus, in the processing method of the related art, it has been impossible to properly form the through-grooves along all the division lines of the workpiece while restraining the processing time from being prolonged.

It is therefore an object of the present invention to provide a laser processing apparatus by which it is possible to properly form through-grooves along all division lines of a workpiece.

In accordance with an aspect of the present invention, there is provided a laser processing apparatus including: a chuck table that holds a workpiece by a holding surface; a laser beam applying unit that applies a pulsed laser beam of such a wavelength as to be absorbed in the workpiece, to the workpiece held by the chuck table; a processing feeding unit that moves the chuck table and the laser beam applying unit in a processing feeding direction relatively to each other; an imaging unit that images the workpiece held by the chuck table; and a control unit that controls at least the chuck table, the laser beam applying unit, the processing feeding unit and the imaging unit. In the laser processing apparatus, the chuck table has: a transparent or semi-transparent holding member that forms the holding surface; and a light emitting body disposed on the side of a surface opposite to the holding surface of the holding member, and the control unit includes: an imaging instruction section that causes the imaging unit to image a processing region of the workpiece while the pulsed laser beam is being applied to the workpiece to form a through-groove in the processing region of the workpiece; and a determination section that detects whether or not light from the light emitting body is imaged in a picked-up image obtained according to the instruction by the imaging instruction section, through the workpiece, and determines a processed state of the through-groove.

Preferably, the control unit causes application of the pulsed laser beam again to the processing region where the through-groove has been determined, by the determination section, to have not been formed properly, to thereby form the through-groove in the processing region.

The laser processing apparatus of the present invention has an effect that through-grooves can be properly formed along all the division lines of the workpiece.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view depicting schematically a configuration example of a laser processing apparatus according to a first embodiment;

FIG. 2A is a perspective view of a wafer constituting a packaged wafer to be processed by the laser processing apparatus according to the first embodiment;

FIG. 2B is a perspective view of a device of the wafer depicted in FIG. 2A;

FIG. 3 is a sectional view of a major part of the packaged wafer to be processed by the laser processing apparatus according to the first embodiment;

FIG. 4 is a perspective view depicting a packaged device chip obtained by dividing the packaged wafer depicted in FIG. 3;

FIG. 5 is a flow chart depicting the flow of a method of manufacturing the packaged wafer to be processed by the laser processing apparatus depicted in FIG. 1;

FIG. 6A is a sectional view of a major part of a wafer during a groove forming step in the method of manufacturing the packaged wafer depicted in FIG. 5;

FIG. 6B is a sectional view of the major part of the wafer after the groove forming step in the method of manufacturing the packaged wafer depicted in FIG. 5;

FIG. 6C is a perspective view of a wafer after the groove forming step in the method of manufacturing the packaged wafer depicted in FIG. 5;

FIG. 7 is a perspective view of the packaged wafer after a molding resin layer forming step in the method of manufacturing the packaged wafer depicted in FIG. 5;

FIG. 8 is a sectional view of a major part of the packaged wafer after the molding resin layer forming step in the method of manufacturing the packaged wafer depicted in FIG. 5;

FIG. 9A is a side view depicting a thinning step in the method of manufacturing the packaged wafer depicted in FIG. 5;

FIG. 9B is a sectional view of the packaged wafer after the thinning step in the method of manufacturing the packaged wafer depicted in FIG. 5;

FIG. 10 is a perspective view depicting a re-attaching step in the method of manufacturing the packaged wafer depicted in FIG. 5;

FIG. 11A is a perspective view depicting a peripheral portion removing step in the method of manufacturing the packaged wafer depicted in FIG. 5;

FIG. 11B is a perspective view of the packaged wafer after the peripheral portion removing step in the method of manufacturing the packaged wafer depicted in FIG. 5;

FIG. 12 is a view depicting the configurations of a chuck table, a laser beam applying unit and an imaging unit of the laser processing apparatus depicted in FIG. 1;

FIG. 13 is a flow chart depicting the flow of a laser processing method using the laser processing apparatus according to the first embodiment;

FIG. 14 is a view depicting a processing step in the laser processing method depicted in FIG. 13;

FIG. 15 is a view depicting an example of a picked-up image obtained by a processing determination step in the laser processing method depicted in FIG. 13;

FIG. 16 is a sectional view depicting an example of a through-groove formed by the processing step in the laser processing method depicted in FIG. 13;

FIG. 17 is a sectional view depicting a state in which the through-groove depicted in FIG. 16 has not been formed properly;

FIG. 18 is a perspective view of a wafer to be processed by a laser processing apparatus according to a second embodiment; and

FIG. 19 is a flow chart depicting the flow of a laser processing method using the laser processing apparatus according to the second embodiment.

### DETAILED DESCRIPTION OF THE PREFERRED EMBODIMENTS

Embodiments of the present invention will be described in detail below, referring to the drawings. It is to be noted, however, that the present invention is not limited by the following description of the embodiments. The constituent elements described below include those easily conceived by a person skilled in the art and the substantial equivalents thereof. Further, the configurations described below can be combined, as required. In addition, various omissions, replacements and modifications of the configurations are possible without departing from the scope of the present invention.

### First Embodiment

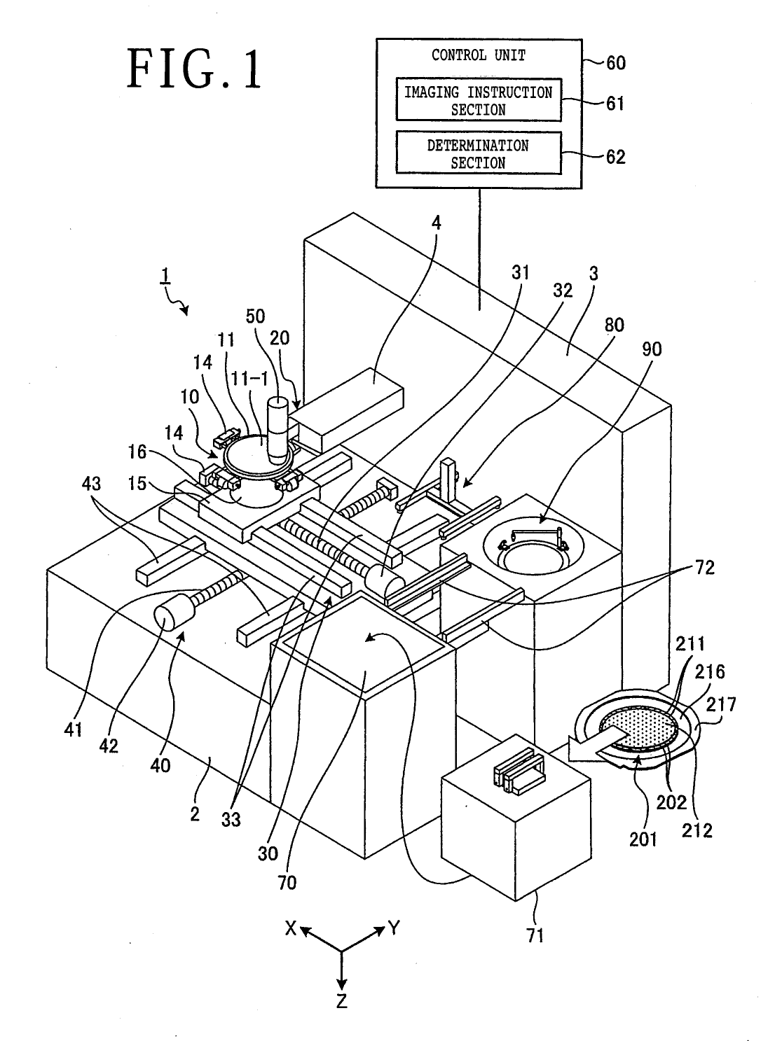

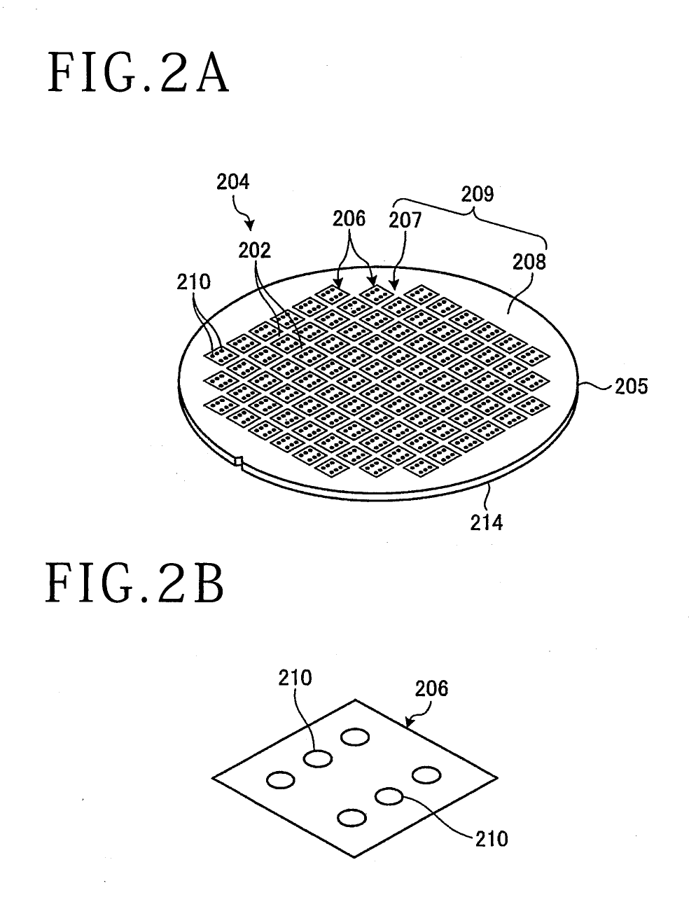

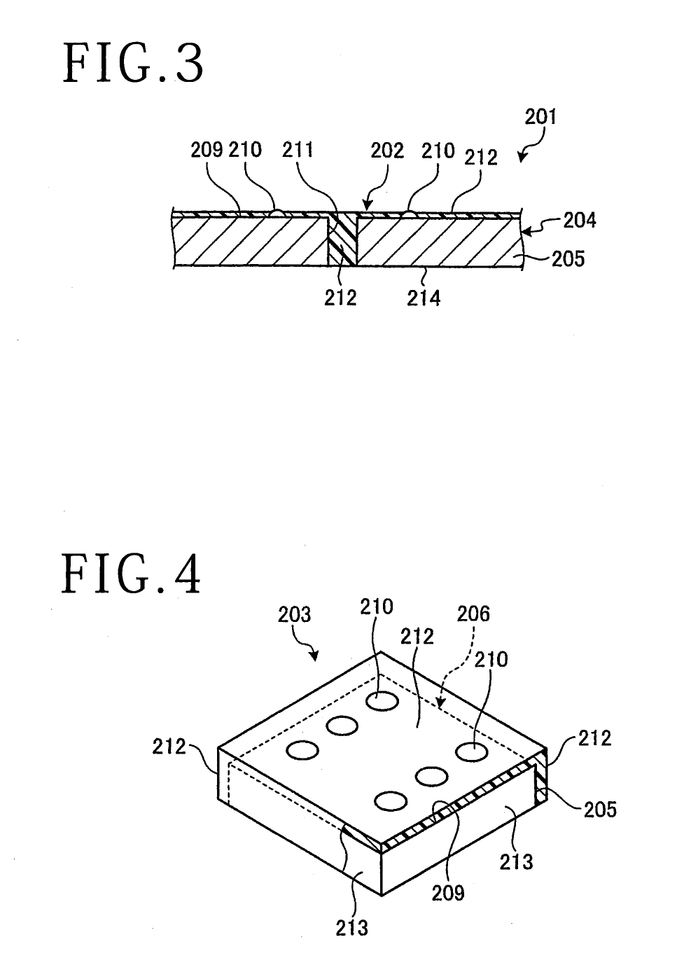

A laser processing apparatus according to a first embodiment will be described. FIG. 1 is a perspective view depicting schematically a configuration example of a laser processing apparatus according to the first embodiment. FIG. 2A is a perspective view of a wafer constituting a packaged wafer to be processed by the laser processing apparatus according to the first embodiment. FIG. 2B is a perspective view of a device of the wafer depicted in FIG. 2A. FIG. 3 is a sectional view of a major part of the packaged wafer to be processed by the laser processing apparatus according to the first embodiment. FIG. 4 is a perspective view depicting a packaged device chip obtained by dividing the packaged wafer depicted in FIG. 3.

A laser processing apparatus 1 depicted in FIG. 1 according to the first embodiment is an apparatus for applying ablation to division lines 202 of a packaged wafer 201 depicted in FIG. 3 as a workpiece, to thereby divide the packaged wafer 201 into packaged device chips 203 depicted in FIG. 4. The packaged wafer 201 to be processed by the laser processing apparatus 1 according to the first embodiment is composed of a wafer 204 depicted in FIG. 2A. The wafer 204 depicted in FIG. 2A, in the first embodiment, is a circular disk-shaped semiconductor wafer or an optical device wafer having a substrate 205 formed from silicon, sapphire, gallium arsenide or the like. As depicted in FIG. 2A, the wafer 204 includes, on a front surface 209, a device region 207 in which devices 206 are each formed in a plurality of respective regions partitioned by a plurality of division lines (streets) 202 intersecting (in the first embodiment, orthogonally intersecting) one another, and a peripheral marginal region 208 surrounding the device region 207. On a front surface of each device 206, a plurality of bumps 210, which are projecting electrodes, are formed, as depicted in FIG. 2B.

As depicted in FIG. 3, the wafer 204 is configured in the form of the packaged wafer 201 in which the front surface 209 of the device region 207 and grooves 211 as processing regions formed in the division line 202 along the division line 202 are covered with a molding resin 212. In other words, the molding resin 212 is placed to cover the upper side of the devices 206 provided on the front surface 209 of the substrate 205 and fill up the grooves 211 between the devices 206. The packed wafer 201 is divided, at the grooves 211 formed in the division lines 202, into the packaged device chips 203 depicted in FIG. 4. The packaged device chip 203 is in a state in which the upper surface and all side surfaces 213 of the device 206 provided on the front surface 209 of the substrate 205 are covered with the molding resin 212, while the bumps 210 are projecting from the molding resin 212 and are exposed.

Note that in the first embodiment, the width of the grooves 211 in the packaged wafer 201 is smaller than the width of the division lines 202, and is, for example, 20 μm. In the first embodiment, the thickness (also called finished thickness) of the packaged wafer 201 is greater than the thickness of the semiconductor wafer to be divided into the devices, and is, for example, 300 μm. In the first embodiment, the plan-view shape of the packaged device chip 203 is greater than that of the devices divided from the semiconductor wafer by use of a cutting blade, and is, for example, a square with each side being 3 mm in length.

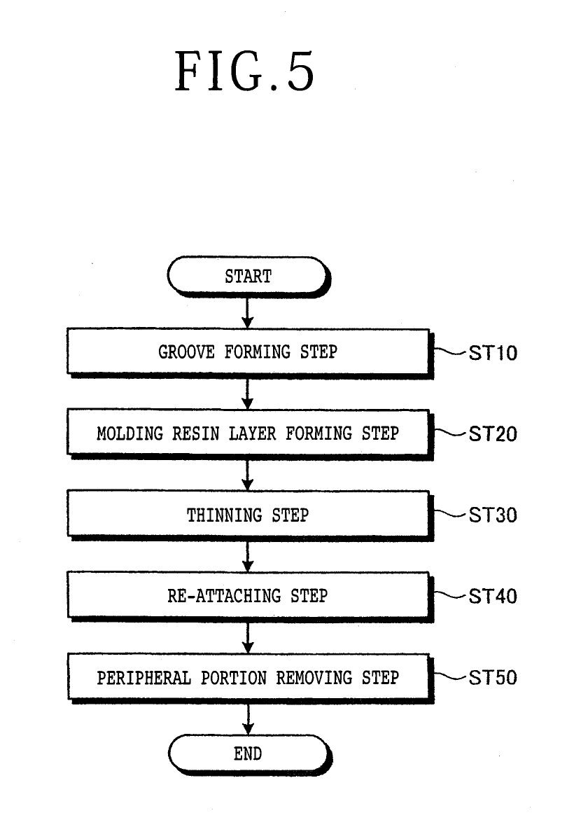

A method of manufacturing the packaged wafer 201, for forming the wafer 204 depicted in FIG. 2A into the packaged wafer 201 depicted in FIG. 3, will be described below, referring to the drawings. As depicted in FIG. 5, the method of manufacturing the packaged wafer 201 according to the first embodiment (this method will hereinafter be referred to simply as the manufacturing method) includes a groove forming step ST10, a molding resin layer forming step ST20, a thinning step ST30, a re-attaching step ST40 and a peripheral portion removing step ST50.

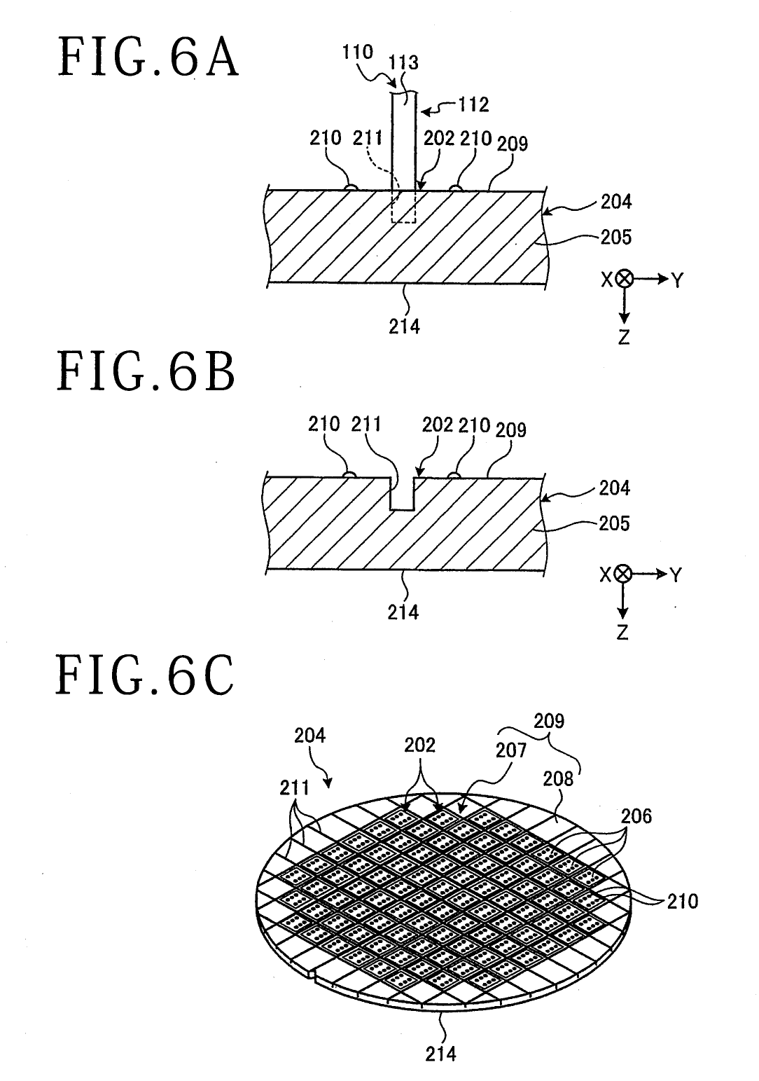

The groove forming step ST10 is a step of forming the groove 211 at each division line 202 of the wafer 204, from the front surface 209. In the groove forming step ST10, the groove 211 extending along the longitudinal direction of each division line 202 is formed at each division line 202. The depth of the grooves 211 formed in the groove forming step ST10 is not less than the finished thickness of the packaged wafer 201. In the first embodiment, in the groove forming step ST10, a back surface 214 on the side opposite to the front surface 209 of the wafer 204 is suction held onto a holding surface of a chuck table of a cutting apparatus 110, and, by use of a cutting blade 113 of cutting means 112 of the cutting apparatus 110 as depicted in FIG. 6A, the grooves 211 are formed in the front surface 209 of the wafer 204, as depicted in FIG. 6B.

In the groove forming step ST10, the chuck table is moved in an X-direction parallel to the horizontal by X-axis moving means (not depicted), the cutting blade 113 of the cutting means 112 is moved in a Y-axis direction parallel to the horizontal and orthogonal to the X-axis direction by Y-axis moving means, and the cutting blade 113 of the cutting means 112 is moved in a Z-axis direction parallel to the vertical direction by Z-axis moving means, whereby the groove 211 is formed in the front surface 209 along each division line 202 of the wafer 204. Note that in the present invention, the grooves 211 may be formed by ablation using a pulsed laser beam, in the groove forming step ST10.

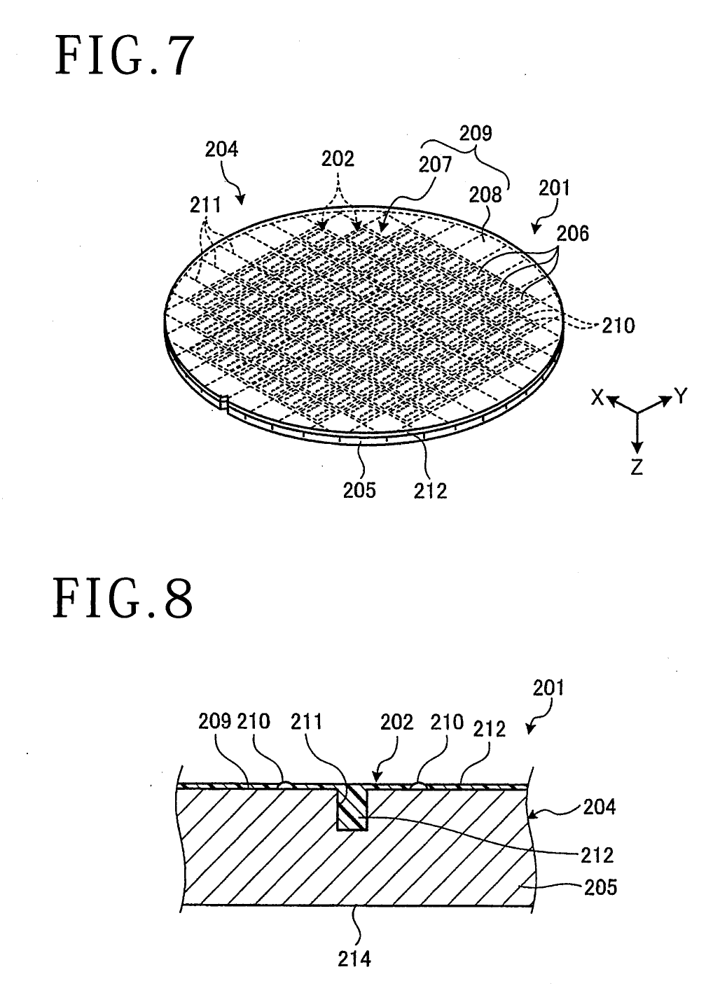

As depicted in FIGS. 7 and 8, the molding resin layer forming step ST20 is a step of covering the front surface 209 in the device region 207 of the wafer 204 and the grooves 211 with the molding resin 212. In the first embodiment, in the molding resin layer forming step ST20, the back surface 214 of the wafer 204 is held on a holding table of a resin coating apparatus, the front surface 209 of the wafer 204 is covered with a mold, and the molding resin 212 is placed to fill the inside of the mold, to cover the whole area of the front surface 209 and the grooves 211 with the molding resin 212. In the first embodiment, a thermoset resin is used as the molding resin 212. In the molding resin layer forming step ST20, the molding resin 212 covering the whole area of the front surface 209 and the grooves 211 of the wafer 204 is cured by heating. In addition, in the first embodiment, the bumps 210 are exposed upon covering the whole area of the front surface 209 and the grooves 211 with the molding resin 212; in the present invention, however, the cured molding resin 212 may be subjected to polishing so as thereby to securely cause the bumps 210 to be exposed.

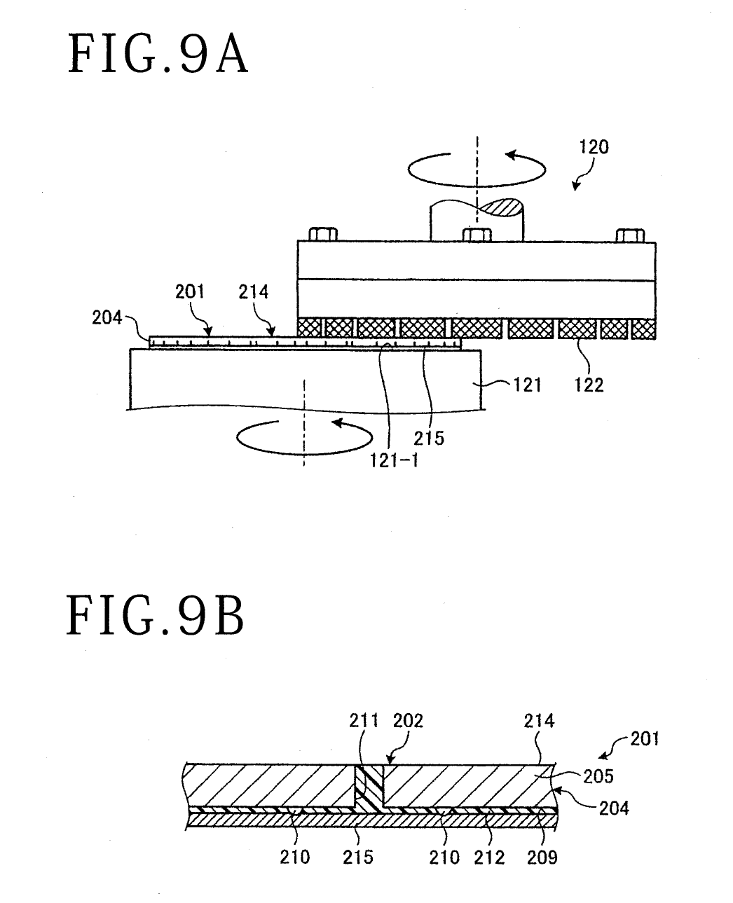

The thinning step ST30 is a step of thinning the substrate 205 of the packaged wafer 201 having the wafer 204 covered with the molding resin 212 to the finished thickness. In the thinning step ST30, as depicted in FIG. 9A, a protective member 215 is attached to the molding resin 212 side of the packaged wafer 201, after which the protective member 215 is suction held onto a holding surface 121-1 of a chuck table 121 of a grinding apparatus 120, grindstones 122 are put in contact with the back surface 214 of the packaged wafer 201, and the chuck table 121 and the grindstones 122 are rotated about axes, whereby the back surface 214 of the packaged wafer 201 is ground. In the thinning step ST30, the packaged wafer 201 is thinned until the molding resin 212 placed to fill the grooves 211 is exposed, as depicted in FIG. 9B.

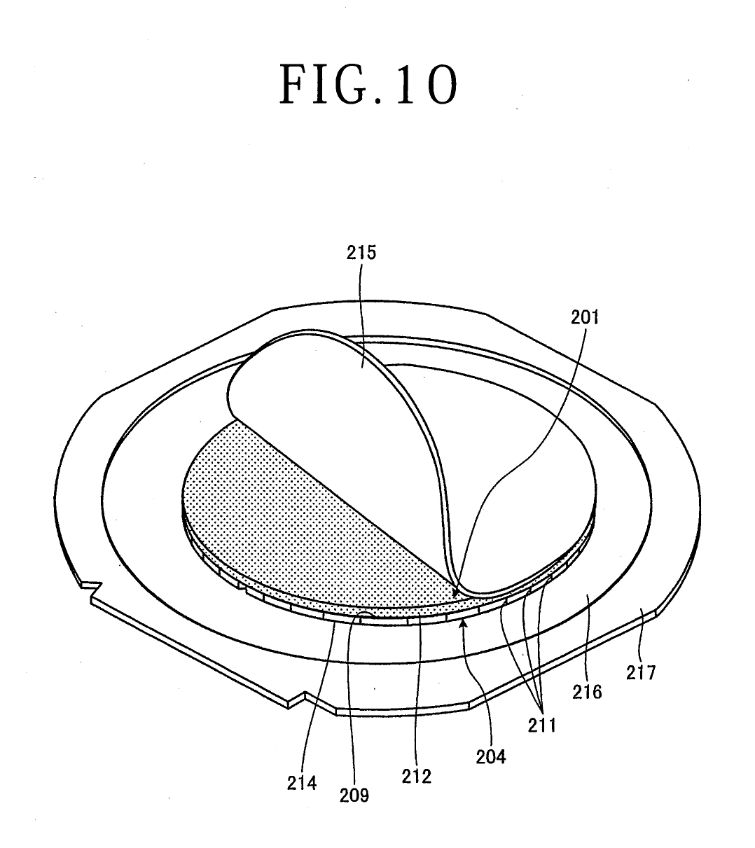

The re-attaching step ST40 is a step of peeling the protective member 215 off the packaged wafer 201 and attaching a dicing tape 216 to the packaged wafer 201. In the re-attaching step ST40, as depicted in FIG. 10, the back surface 214 of the packaged wafer 210 is attached to the dicing tape 216 to the periphery of which an annular frame 217 has been attached, and the protective member 215 is peeled off the front surface 209.

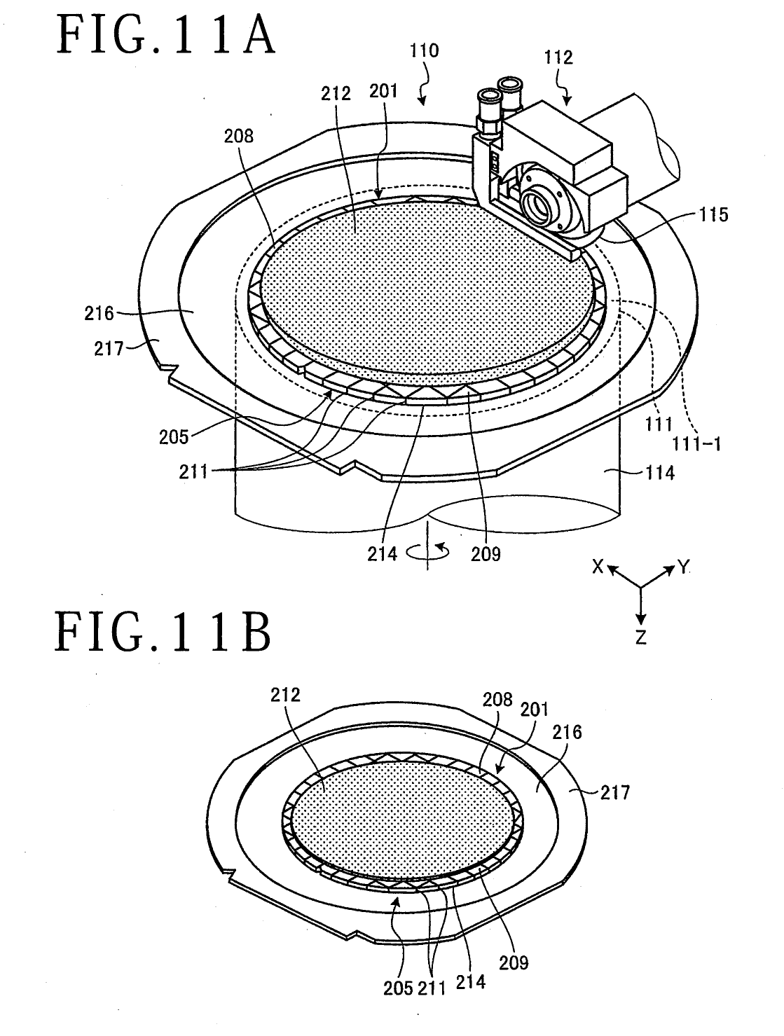

The peripheral portion removing step ST50 is a step of removing the molding resin 212 along a peripheral edge of the packaged wafer 201 and causing the grooves 211 filled with the molding resin 212 to be exposed in a peripheral marginal region 208. In the first embodiment, in the peripheral portion removing step ST50, the molding resin 212 is removed along the whole circumference of the peripheral edge of the peripheral marginal region 208 of the packaged wafer 201. In the first embodiment, in the peripheral portion removing step ST50, similarly to the groove forming step ST10, as depicted in FIG. 11A, the back surface 214 of the packaged wafer 201 is suction held onto a holding surface 111-1 of a chuck table 111 of a cutting apparatus 110, the chuck table 111 is rotated about an axis parallel to the Z-axis direction by a rotational drive source 114, and, while keeping the rotation, a cutting blade 115 is made to cut into the molding resin 212 on the peripheral edge of the peripheral marginal region 208 until reaching the substrate 205, whereby the grooves 211 filled with the molding resin 212 are exposed on the peripheral edge of the peripheral marginal region 208. In the peripheral portion removing step ST50, the molding resin 212 at the peripheral edge of the peripheral marginal region 208 of the packaged wafer 201 is removed, as depicted in FIG. 11B. Note that in FIGS. 10, 11A and 11B, the bumps 210 are omitted.

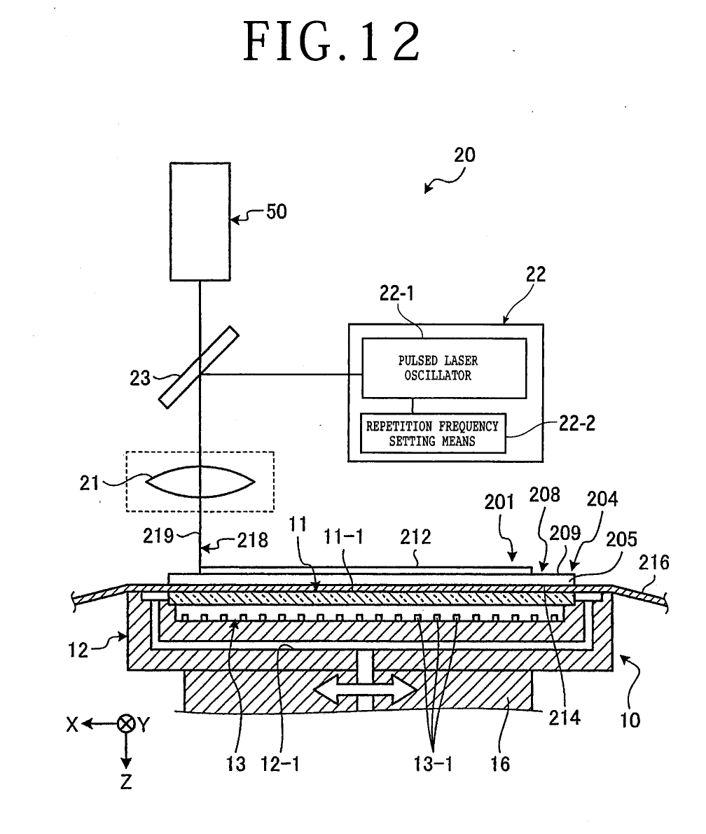

The configuration of the laser processing apparatus 1 according to the first embodiment will be described below, referring to the drawings. FIG. 12 is a view depicting the configurations of a chuck table, a laser beam applying unit and an imaging unit of the laser processing apparatus depicted in FIG. 1.

The laser processing apparatus 1 is an apparatus for applying a pulsed laser beam 218 (depicted in FIG. 12) to the molding resin 212 in the grooves 211 of the packaged wafer 201, thereby to subject the packaged wafer 201 to ablation and thereby to divide the packaged wafer 201 into the packaged device chips 203. As depicted in FIG. 1, the laser processing apparatus 1 includes the chuck table 10 that holds the packaged wafer 201 on a holding surface 11-1, a laser beam applying unit 20, X-axis moving means 30 as a processing feeding unit, Y-axis moving means 40 as an indexing feeding unit, an imaging unit 50, and a control unit 60.

The X-axis moving means 30 is for moving the chuck table 10 in the X-axis direction, which is a processing feeding direction parallel to the horizontal of an apparatus main body 2, to thereby move the chuck table 10 and the laser beam applying unit 20 relatively to each other in the X-axis direction. The Y-axis moving means 40 is for moving the chuck table 10 in the Y-axis direction, which is an indexing feeding direction being parallel to the horizontal and being orthogonal to the X-axis direction, thereby to move the chuck table 10 and the laser beam applying unit 20 relatively to each other in the Y-axis direction.

The X-axis moving means 30 and the Y-axis moving means 40 have known ball screws 31 and 41, respectively, provided to be rotatable about respective axes, known pulse motors 32 and 42 for rotating the ball screws 31 and 41 about the respective axes, and known guide rails 33 and 43 for supporting the chuck table 10 movably in the X-axis direction and Y-axis direction, respectively. In addition, the X-axis moving means 30 has X-axis direction position detection means (not depicted) for detecting the position of the chuck table 10 in the X-axis direction, and the Y-axis moving means 40 has Y-axis direction position detection means (not depicted) for detecting the position of the chuck table 10 in the Y-axis direction. The X-axis direction position detection means and the Y-axis direction position detection means can each be comprised of a linear scale parallel to the X-axis direction or Y-axis direction, and a reading head. The X-axis direction position detection means and the Y-axis direction position detection means outputs the position of the chuck table 10 in the X-axis direction or Y-axis direction to the control unit 60. Besides, the laser processing apparatus 1 includes a rotational drive source 16 for rotating the chuck table 10 about an axis parallel to the Z-axis direction which is orthogonal to both the X-axis direction and the Y-axis direction. The rotational drive source 16 is disposed on a moving table 15 which is movable in the X-axis direction by the X-axis moving means 30.

The laser beam applying unit 20 is for applying a pulsed laser beam 218 from above toward the front surface 209 of the packaged wafer 201 held on the holding surface 11-1 of the chuck table 10, to thereby subject the packaged wafer 201 to ablation. The pulsed laser beam 218 is a pulse form laser beam having such a wavelength (e.g., 355 nm) as to be absorbed in the molding resin 212 placed to fill the grooves 211 of the packaged wafer 201 and having a fixed laser power. The laser beam applying unit 20 is mounted to the tip of a support column 4 continuous with a wall section 3 erected from the apparatus main body 2. As the wavelength of the pulsed laser beam 218, other wavelength than the above-mentioned, for example, 532 nm can also be used, and wavelengths of 200 to 1200 nm absorbable in the molding resin 212 can be used.

As depicted in FIG. 12, the laser beam applying unit 20 includes: a focusing lens 21 for focusing the pulsed laser beam 218 to be applied to the front surface of the packaged wafer 201; a driving mechanism (not depicted) for moving a focal point of the pulsed laser beam 218 in the Z-axis direction; a laser beam oscillation unit 22 for oscillating the pulsed laser beam 218; and a dichroic mirror 23 for reflecting the pulsed laser beam 218 oscillated by the laser beam oscillation unit 22 toward the focusing lens 21. The laser beam oscillation unit 22 includes a pulsed laser oscillator 22-1 for oscillating the pulsed laser beam 218 of a wavelength of 355 nm, and repetition frequency setting means 22-2 for setting a repetition frequency of the pulsed laser beam 218 oscillated by the pulsed laser oscillator 22-1. In the first embodiment, an optical path 219 of the pulsed laser beam 218 applied toward the front surface 209 of the packaged wafer 201 by the laser beam applying unit 20 is parallel to the Z-axis direction. The dichroic mirror 23 reflects the pulsed laser beam 218 oscillated from the pulsed laser oscillator 22-1, and transmits light of other wavelengths than the wavelength of the pulsed laser beam 218.

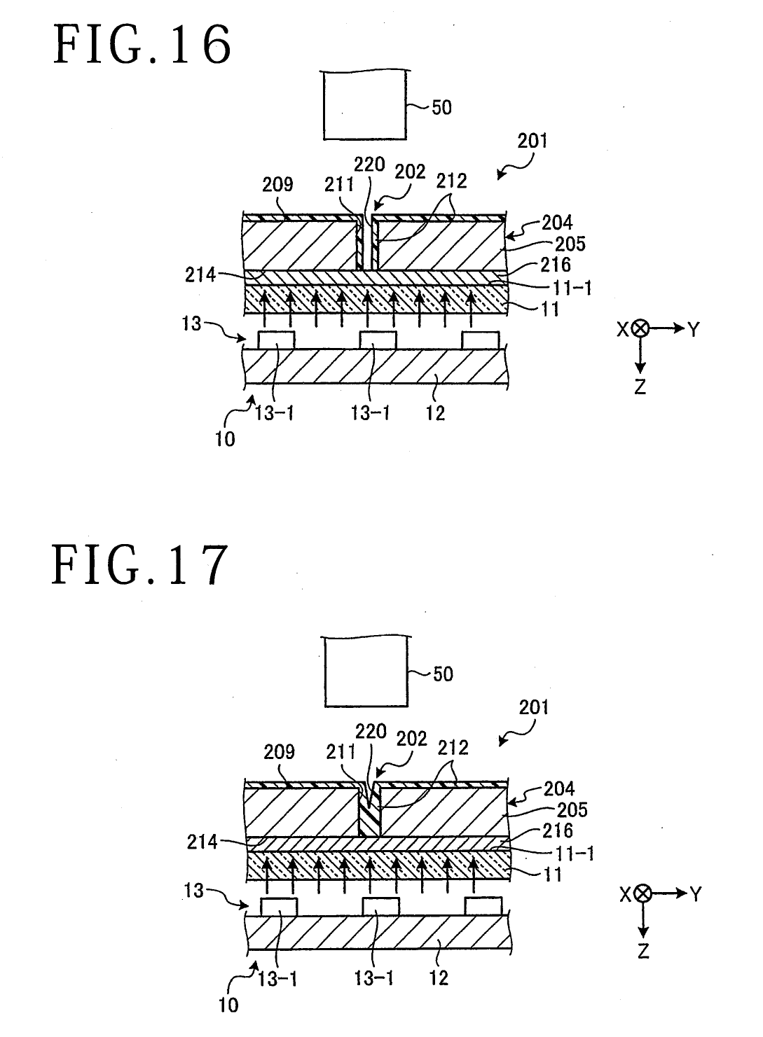

The laser beam applying unit 20, while being moved relatively to the packaged wafer 201 held on the chuck table 10 by the X-axis moving means 30 and the Y-axis moving means 40, applies the pulsed laser beam 218 to the molding resin 212 in the groove 211 at each division line 202, to form a through-groove 220 (depicted in FIG. 16) along each division line 202 in the molding resin 212 in the groove 211. The laser beam applying unit 20 applies the pulsed laser beam 218 to the molding resin 212 in the groove 211 at each division line 202, while being moved multiple times in the X-axis direction relatively to the packaged wafer 20. Note that a movement of the laser beam applying means 20 in the X-axis direction once is referred to as “one pass,” and in the first embodiment, the laser beam applying unit 20 applies the pulsed laser beam 218 while being moved “three passes” or “four passes” relative to the packaged wafer 201, thereby forming the through-groove 220 along each division line 202.

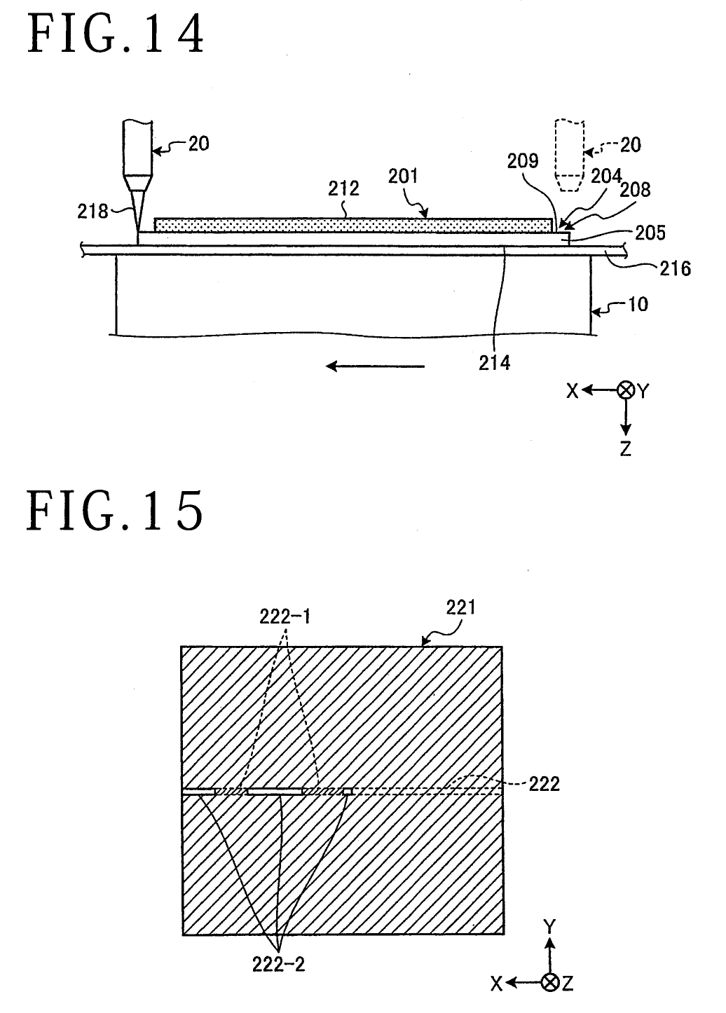

The imaging unit 50 is for imaging the packaged wafer 201 held by the chuck table 10. The imaging unit 50 is disposed on the upper side of the dichroic mirror 23, and is disposed at a position aligned with the dichroic mirror 23 in the Z-axis direction. The imaging unit 50 is comprised of a charge-coupled device (CCD) camera which images the light transmitted through the dichroic mirror 23, thereby imaging the packaged wafer 201 held by the chuck table 10. The imaging unit 50 outputs a picked-up image 221 (depicted in FIG. 15) picked up by the CCD camera to the control unit 60. In the first embodiment, the optical path of the CCD camera of the imaging unit 50 is set coaxial with the optical path 219 of the pulsed laser beam 218 applied through the focusing lens 21 to the front surface 209 of the packaged wafer 201.

In addition, the laser processing apparatus 1 includes a cassette 71 in which a plurality of packaged wafers 201 each supported on the annular frame 217 by the dicing tape 216 are accommodated, and a cassette elevator 70 on which the cassette 71 is placed and by which the cassette 71 is moved in the Z-axis direction. The laser processing apparatus 1 includes: carrying-in/out means for taking out the packaged wafer 201 yet to be subjected to ablation from the cassette 71 and for accommodating the packaged wafer 201 having undergone ablation into the cassette 71; and a pair of rails 72 on which the packaged wafer 201 that is yet to be subjected to ablation and that has been taken out of the cassette 71 and the packaged wafer 201 that has undergone ablation and that is yet to be accommodated into the cassette 71 are each temporarily placed. The laser processing apparatus 1 includes: a cleaning unit 90 for cleaning the packaged wafer 201 having undergone ablation; and a carrying unit 80 for carrying the packaged wafer 201 between the pair of rails 72 and the chuck table 10 and the cleaning unit 90.

As depicted in FIG. 12, the chuck table 10 includes: a transparent or semi-transparent holding member 11 forming the holding surface 11-1; an annular frame section 12 formed to surround the holding member 11; and a light emitting body 13 disposed on the side of a surface opposite to the holding surface 11-1 of the holding member 11. The holding member 11 is formed in the shape of a circular disk with a thickness of 2 to 5 mm from, for example, quartz. The holding member 11 has its upper surface functioning as the holding surface 11-1 for holding the packaged wafer 201 thereon.

The annular frame section 12 is composed of a peripheral portion that surrounds and supports the periphery of the holding member 11, and a base section from which the peripheral portion is erected. As depicted in FIG. 12, the annular frame section 12 has its surface disposed on the same plane as the holding surface 11-1. The annular frame section 12 is mounted to the rotational drive source 16. In addition, the annular frame section 12 is provided with a suction passage 12-1 opening at an outer edge of the holding member 11 and connected to a vacuum suction source (not depicted).

The light emitting body 13 is mounted to the base section of the annular frame section 12, and is disposed to face a lower surface of the holding member 11. The light emitting body 13 is composed of a plurality of light emitting diodes (LEDs) 13-1. Each of the LEDs 13-1 is connected to a power circuit (not depicted). When electric power is supplied from the power circuit to each LED 13-1, the light emitting body 13 emits light, and casts the light upward from the lower side of the holding member 11.

The chuck table 10 has the annular frame section 12 mounted to the rotational drive source 16, whereby the chuck table 10 is provided to be movable in the X-axis direction by the X-axis driving means 30, be movable in the Y-axis direction by the Y-axis moving means 40 and be rotatable about an axis by the rotational drive source 16. Besides, the chuck table 10 suction holds the packaged wafer 201 through a process in which the packaged wafer 201 held by the annular frame 217 is placed on the holding surface 11-1 via the dicing tape 216 and suction is applied by the vacuum suction source. In addition, in the periphery of the chuck table 10, clamp sections 14 for clamping the annular frame 217 are provided.

The control unit 60 is for controlling the aforementioned constituent elements of the laser processing apparatus 1, thereby to cause the laser processing apparatus 1 to perform a processing operation on the packaged wafer 201. Note that the control unit 60 is a computer. The control unit 60 is connected to a display apparatus (not depicted) comprised of a liquid crystal display or the like for displaying an image of a state of the processing operation and the like and an input apparatus (not depicted) through which the operator registers information on the contents of processing and the like. The input apparatus is composed of at least one of a touch panel provided in the display apparatus and an external input apparatus such as a keyboard.

The control unit 60 performs alignment for detecting that position of the packaged wafer 201 to which the pulsed laser beam 218 is to be applied, before ablation of the packaged wafer 201. In carrying out the alignment, the control unit 60 causes the imaging unit 50 to image each of the grooves 211 exposed at the peripheral edge of the peripheral marginal region 208 of the packaged wafer 201, and detects that position of the groove 211 formed at each division line 202 to which the pulsed laser beam 218 is to be applied, based on the image obtained by the imaging and the results of detection by the X-axis direction position detection means and the Y-axis direction position detection means.

As depicted in FIG. 1, the control unit 60 includes at least an imaging instruction section 61 and a determination section 62. The imaging instruction section 61 causes the imaging unit 50 to image the molding resin 212 which is placed to fill the grooves 211 of the packaged wafer 201 and in the state immediately upon application of the pulsed laser beam 218 thereto while the pulsed laser beam 218 is being applied to the packaged wafer 201 to form the through-groove 220 in the molding resin 212 placed to fill the groove 211 of the packaged wafer 201. In the first embodiment, the imaging instruction section 61 of the control unit 60 causes the imaging unit 50 to image the front surface 209 of the packaged wafer 201 between an application timing and an application timing for applying the pulsed laser beam 218 while the through-groove 220 is being formed in the molding resin 212 placed to fill the groove 211 of the packaged wafer 201.

The determination section 62 detects whether or not the light from the light emitting body 13 is imaged in the picked-up image 221 obtained by imaging by the imaging unit 50 according to the instruction by the imaging instruction section 61, through the packaged wafer 201, thereby to determine the processed state of the through-groove 220. The determination section 62 detects that position 222 (indicated by dotted lines in FIG. 15) in the picked-up image 221 to which the pulsed laser beam 218 is to be applied, from the position to which the pulsed laser beam 218 is to be applied and which has been detected by performing the alignment and the like. The determination section 62 determines that the through-groove 220 has been formed satisfactorily when the quantity of light at the position 222 to which to apply the pulsed laser beam 218 is not less than a predetermined quantity of light. In addition, the determination section 62 determines that the through-groove 200 has not been formed properly (the through-groove 220 is not penetrating the packaged wafer 201) when the quantity of light at the position 222 to which to apply the pulsed laser beam 218 is less than the predetermined quantity of light. When the quantity of light at the position 222 to which to apply the pulsed laser beam 218 is less than the predetermined quantity of light, the determination section 62 detects the position where the through-groove 220 has not been formed properly.

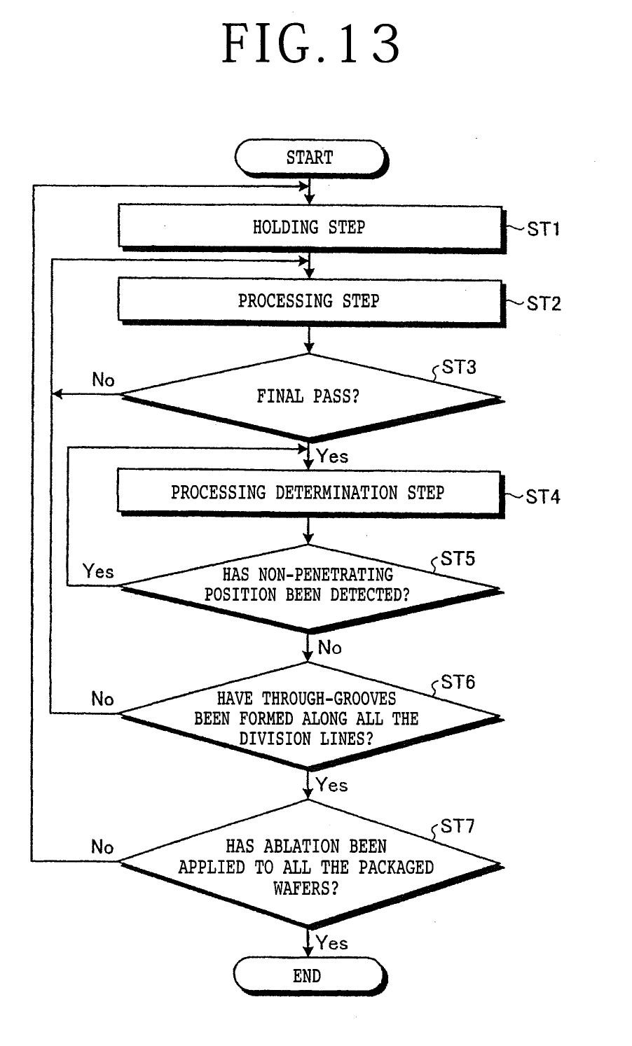

A laser processing method using the laser processing apparatus 1 will be described below, referring to the drawings. FIG. 13 is a flow chart depicting the flow of the laser processing method using the laser processing apparatus according to the first embodiment. The laser processing method using the laser processing apparatus 1 (this method will hereinafter be referred to as the processing method) is a manufacturing method for manufacturing the packaged device chips 203 by applying the pulsed laser beam 218 to the molding resin 212 placed to fill the grooves 211 of the packaged wafer 201, thereby dividing the molding resin 212 filling the grooves 211. As depicted in FIG. 13, the processing method includes at least a holding step ST1, a processing step ST2, and a processing determination step ST4.

In the processing method, first, the operator registers information on the contents of processing in the control unit 60 of the laser processing apparatus 1, the operator accommodates into the cassette 71 the packaged wafer 201 supported by the annular frame 217, and the operator places the cassette 71 on the cassette elevator 70 of the laser processing apparatus 1. In the processing method, the laser processing apparatus 1 starts a processing operation when an instruction to start the processing operation is given from the operator.

In the processing method, first, the holding step ST1 is carried out. The holding step ST1 is a step of holding the packaged wafer 201 on the holding surface 11-1 of the holding member 11. In the holding step ST1, the control unit 60 causes the carrying-in/out means to take out one sheet of packaged wafer 201 yet to be subjected to ablation from the cassette 71, and to place it on the pair of rails 72. The control unit 60 causes the carrying unit 80 to place the packaged wafer 201, present on the pair of rails 72, onto the holding surface 11-1 of the holding member 11 of the chuck table 10, whereby the packaged wafer 201 is suction held on the holding surface 11-1 of the holding member 11 of the chuck table 10. The control unit 60 proceeds to the processing step ST2.

In the processing step ST2, the control unit 60 causes the X-axis moving means 30 and the Y-axis moving means 40 to move the chuck table 10 toward a position under the laser beam applying unit 20 so that the packaged wafer 201 held on the chuck table 10 is positioned under the imaging unit 50, that is, under the laser beam applying unit 20. In the processing step ST2, the control unit 60 causes the imaging unit 50 to image the groove 211 formed at each division line 202 exposed in the peripheral marginal region 208 of the packaged wafer 201, and performs alignment of each division line 202.

Then, based on the information on the contents of processing, the control unit 60 causes the X-axis moving means 30 and the Y-axis moving means 40 to move the laser beam applying unit 20 to a position for facing one end of that division line 202 of the packaged wafer 201, to which to apply the pulsed laser beam 218 first, and causes the rotational drive source 16 to set the division line 202 to which to apply the pulsed laser beam 218 first, parallel to the X-axis direction. As depicted in FIG. 14, the control unit 60 causes the laser beam applying unit 20 to apply the pulsed laser beam 218 while causing the X-axis moving means 30 to move the chuck table 10 by one pass along the X-axis direction.

After causing the X-axis moving means 30 to move the chuck table 10 by one pass along the X-axis direction, the control unit 60 refers to the information on the contents of processing and determines whether or not the next pass is a final pass (step ST3). When it is determined that the next pass is not the final pass (step ST3: No), the control unit 60 returns to the processing step ST2, and performs the processing step ST2 of the next pass.

When it is determined that the next pass is the final pass (step ST3: Yes), the control unit 60 proceeds to the processing determination step ST4. The processing determination step ST4 is a step of detecting whether or not the light from the light emitting body 13 is imaged in the picked-up image 2 which is obtained by imaging the groove 211 of the packaged wafer 201 and an example of which is depicted in FIG. 15, through the packaged wafer 201, to thereby determine the processed state of the through-groove 220, while the pulsed laser beam 218 is being applied to the packaged wafer 201 to form the through-groove 220 in the molding resin 212 filling the groove 211. Note that in the picked-up image 221 in FIG. 15, positions where the quantity of light is less than the predetermined quantity of light are indicated by parallel slant lines, whereas the positions where the quantity of light is not less than the predetermined light are indicated by a solid white state.

In the processing determination step ST4, the imaging instruction section 61 of the control unit 60 causes the imaging unit 50 to image the front surface 209 of the packaged wafer 201 between a pulse and a pulse in application of the pulsed laser beam 218, while the X-axis moving means 30 is moving the chuck table 10 by the final pass along the X-axis direction and while the laser beam applying unit 20 is applying the pulsed laser beam 218 to the packaged wafer 201 to form the through-groove 220. In the first embodiment, in the processing determination step ST4, the imaging instruction section 61 of the control unit 60 causes the imaging unit 50 to image the front surface 209 of the packaged wafer 201 multiple times to obtain a plurality of picked-up images 221 during when the chuck table 10 is moved in the final pass.

In the processing determination step ST4, the determination section 62 of the control unit 60 determines whether or not a position 222-1 (indicated by dense parallel slant lines in FIG. 15) where the quantity of light at the position 222 to which to apply the pulsed laser beam 218 is less than the predetermined quantity of light is present in at least one of all the picked-up images 221. In the processing determination step ST4, at the position 222-2 indicated by a solid white state in FIG. 15 where the quantity of light is determined by the determination section 62 of the control unit 60 to be not less than the predetermined quantity of light, the through-groove 220 is formed to penetrate the molding resin 212 filling the groove 211 of the packaged wafer 201, and the light from the light emitting body 13 passes through the holding member 11 and the through-groove 220, to be received by the imaging unit 50, as depicted in FIG. 16. In addition, in the processing determination step ST4, at the position 222-1 indicated by dense parallel slant lines in FIG. 15 where the quantity of light is determined by the determination section 62 of the control unit 60 to be less than the predetermined quantity of light, the through-groove 220 does not penetrate the molding resin 212 filling the groove 211 of the packaged wafer 201, and the molding resin 212 remains at the bottom of the through-groove 220 as depicted in FIG. 17, so that the light from the light emitting body 13 is not received by the imaging unit 50. Note that in FIGS. 16 and 17, the bumps 210 are omitted.

In the processing determination step ST4, when it is determined by the determination section 62 of the control unit 60 that a position 222-1 where the quantity of light is less than the predetermined quantity of light is present in at least one of all the picked-up images 221, the position where the quantity of light is less than the predetermined quantity of light is detected, and the detected position is stored as a position where the through-groove 220 has not been formed properly. Then, the control unit 60 determines whether or not a position where the through-groove 220 has not been formed properly has been detected in the processing detection step ST4 (step ST5). When it is determined that a position where the through-groove 220 has not been formed properly has been detected in the processing determination step ST4 (step ST5: Yes), the control unit 60 returns to the processing determination step ST4. In the processing determination step ST4 to which the control unit 60 has thus returned, the control unit 60 causes the pulsed laser beam 218 to be again applied to the molding resin 212 filling the groove 211 at the position where the through-groove 220 has been determined, by the determination section 62, to have not been formed properly, to form the through-groove 220 in the molding resin 212, and, in addition, obtains a picked-up image 221 and determines whether or not there is a position 222-1 where the quantity of light is less than the predetermined quantity of light.

When it is determined that a position where the through-groove 220 has not been formed properly has not been detected in the processing determination step ST4 (step ST5: No), the control unit 60 determines whether or not the through-grooves 220 have been formed along all the division lines 202 of the packaged wafer 201 held on the chuck table 10 (step ST6). When it is determined that the through-grooves 220 have not been formed along all the division lines 202 of the packaged wafer 201 held on the chuck table 10 (step ST6: No), the control unit 60 returns to the processing step ST2, and repeats the steps ranging from the processing step ST2 to the step ST5, to apply the pulsed laser beam 218 to the molding resin 212 filling the groove 211 along the next division line 202.

When it is determined that the through-grooves 220 have been formed along all the division lines 202 of the packaged wafer 201 held on the chuck table 10 (step ST6: Yes), the control unit 60 retracts the chuck table 10 from the position under the laser beam applying unit 20, and releases the suction holding by the chuck table 10. Then, the control unit 60 uses the carrying unit 80 to carry the ablation-processed packaged wafer 201 to the cleaning unit 90, cleans the packaged wafer 201 by the cleaning unit 90, and accommodates the cleaned packaged wafer 201 into the cassette 71.

The control unit 60 determines whether or not the ablation has been applied to all the packaged wafers 201 in the cassette 71 (step ST7). When it is determined that the ablation has not been applied to all the packaged wafers 201 in the cassette 71 (step ST7: No), the control unit 60 returns to the holding step ST1, places a packaged wafer 201 yet to be subjected to ablation on the chuck table 10 again, and repeats the steps ranging from the holding step ST1 to the step ST6, to divide all the packaged wafers 201 in the cassette 71 into individual packaged device chips 203. When it is determined that the ablation has been applied to all the packaged wafers 201 in the cassette 71 (step ST7: Yes), the control unit 60 finishes the processing operation.

The aforementioned control unit 60 includes an arithmetic operation apparatus having a microprocessor such as a central processing unit (CPU), a storage apparatus having a memory such as a read only memory (ROM) or a random access memory (RAM), and an input/output interface apparatus. The arithmetic operation apparatus of the control unit 60 performs arithmetic operations according to a computer program stored in the storage apparatus, and outputs control signals for controlling the laser processing apparatus 1 to the aforementioned constituent elements of the laser processing apparatus 1 through the input/output interface apparatus. In addition, the functions of the imaging instruction section 61 and the determination section 62 of the control unit 60 are realized by the arithmetic operation apparatus executing the computer program stored in the storage apparatus and by storing required information in the storage apparatus.

In the laser processing apparatus 1 according to the first embodiment, the imaging unit 50 is disposed coaxially with an optical path 219 of the pulsed laser beam 218, and the imaging unit 50 is operated to image the packaged wafer 201 between the application timings of the pulsed laser beam 218. Therefore, the laser processing apparatus 1 can image the packaged wafer 201 by the imaging unit 50, while ablation is being conducted, by emitting light from the light emitting body 13 in the chuck table 10. Accordingly, the processed state of the through-groove 220 undergoing the ablation can be determined based on whether or not the light from the chuck table 10 is detected in the picked-up image 221.

In addition, the laser processing apparatus 1 again applies the pulsed laser beam 218 to the molding resin 212 filling the groove 211 where the through-groove 220 has been determined to have not been formed properly. As a result, the laser processing apparatus 1 can form properly the through-grooves 220 along all the division lines 202 of the packaged wafer 201. Accordingly, the laser processing apparatus 1 produces an effect that the through-grooves 220 can be properly formed along all the division lines 202 of the packaged wafer 201.

Besides, the laser processing apparatus 1 again applies the pulses laser beam 218 to the molding resin 212 filling the groove 211 where the through-groove 220 has been determined to have not been formed properly, and, therefore, ablation can be applied directly to the groove 211 where the through-groove 220 has not been formed properly, without peeling the packaged wafer 201 from the chuck table 10. Ordinarily, when the packaged wafer 201 divided along the through-grooves 220 into packaged device chips 203 is detached from the chuck table 10, the packaged device chips 203 would move to cause the division lines 202 to become non-straight lines, so that it becomes difficult to apply the pulsed laser beam 218 to the packaged wafer 201 while performing processing feeding again. The laser processing apparatus 1, however, produces an effect that the through-grooves 220 can be properly formed along all the division lines 202 of the packaged wafer 201.

In addition, the laser processing apparatus 1 can determine the processed state of the through-groove 220 during the ablation. Therefore, notwithstanding it is determined whether or not the through-groove 220 has been formed, the time required for processing can be restrained from being prolonged.

### Second Embodiment

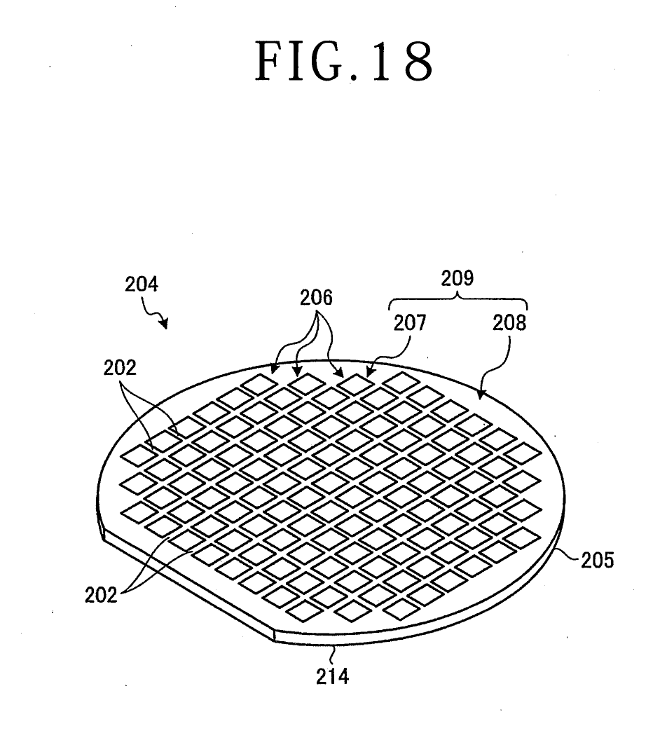

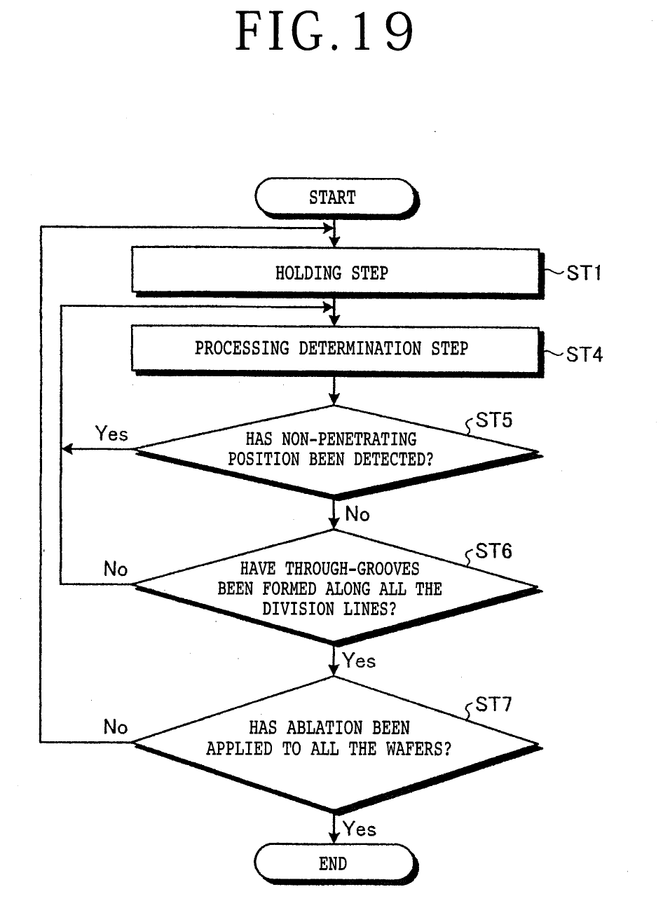

A laser processing apparatus according to a second embodiment will be described. FIG. 18 is a perspective view of a wafer to be processed by the laser processing apparatus according to the second embodiment. FIG. 19 is a flow chart depicting the flow of a laser processing method using the laser processing apparatus according to the second embodiment. In FIGS. 18 and 19, the same sections as those in the first embodiment described above are denoted by the same symbols as used above, and descriptions thereof are omitted.

The laser processing apparatus 1 according to the second embodiment is for processing a wafer 204 as a workpiece depicted in FIG. 18, wherein the laser processing method is different from that in the first embodiment, but the configuration of the apparatus itself is the same as in the first embodiment. In the laser processing method using the laser processing apparatus 1 according to the second embodiment, the wafer 204 is one formed on its front surface 209 with a low-dielectric-constant insulator film (low-k film) or one in which devices 206 are each an imaging element such as a complementary metal oxide semiconductor (MOS))CMOS. The low-dielectric-constant insulator film is comprised of an inorganic film of SiOF or BSG (SiOB) or the like and an organic film such as a polyimide or parylene polymer film. The wafer 204 is accommodated in a cassette 71 in a state in which its front surface 209 is attached to a dicing tape 216 accompanied by an annular frame 217 attached to a peripheral portion thereof, it is cut along division lines 202 from its back surface 214 side, and cut grooves are formed on its front surface 209 side while leaving a cutting allowance of a predetermined thickness. During when the wafer 204 is moved one pass by X-axis moving means 30, a through-groove 220 for cutting the cutting allowance is formed by a laser beam applying unit 20.

In the laser processing method using the laser processing apparatus 1 according to the second embodiment, after a holding step ST1 the control proceeds to a processing determination step ST4, then, when it is determined by a control unit 60 that through-grooves 220 have not yet been formed along all the division lines 202 of the wafer 204 held on a chuck table 10 (step ST6: No), the control returns to the processing determination step ST4, and the through-groove 220 is formed along the next division line 202. In other points, the laser processing method is the same as in the first embodiment described above.

The laser processing apparatus 1 according to the second embodiment can determine, in the processing determination step ST4, the processed state of the through-groove 220 during ablation, like in the first embodiment. Therefore, the laser processing apparatus 1 according to the second embodiment produces an effect that the through-grooves 220 can be properly formed along all the division lines 202 of the wafer 204.

Note that according to the laser processing apparatuses according to the first embodiment and the second embodiment, the following laser processing methods and the following methods of manufacturing a packaged device chip can be obtained.

### <Supplementary Note 1>

A laser processing method including:

a holding step of holding a workpiece on a holding surface of a transparent or semi-transparent holding member; and

a processing determination step of determining a processed state of a through-groove by emitting light from a light emitting body disposed on the side of a surface opposite to the holding surface of the holding member, and detecting whether or not the light from the light emitting body is imaged in a picked-up image obtained by imaging processing regions of the workpiece, through the workpiece, while a pulsed laser beam is being applied to the workpiece to form the through-groove in the processing region of the workpiece.

### <Supplementary Note 2>

The laser processing method as described in Supplementary Note 1, in which in the processing determination step, the pulsed laser beam is again applied to the processing region where the through-groove has been determined to have not been formed properly, to thereby form the through-groove.

### <Supplementary Note 3>

A method of manufacturing a packaged device chip, for manufacturing packaged device chips in each of which an upper surface and all side surfaces of the device is covered with a molding resin by dividing processing regions of a packaged wafer which is provided with devices on a front surface thereof and in which the molding resin is placed to cover an upper side of the devices and fill the processing regions between the devices, the method including:

a holding step of holding a back surface side of the packaged wafer on a holding surface of a transparent or semi-transparent holding member; and

a processing determination step of determining a processed state of the through-groove by emitting light from a light emitting body disposed on the side of a surface opposite to the holding surface of the holding member, and detecting whether or not the light from the light emitting body is imaged in a picked-up image obtained by imaging the processing regions of the packaged wafer, through the packaged wafer, while a pulsed laser beam is being applied to the front surface side of the packaged wafer to form a through-groove in the processing region.

### <Supplementary Note 4>

The method of manufacturing a packaged device as described in Supplementary Note 3, in which in the processing determination step, the pulsed laser beam is again applied to the processing region where the through-groove has been determined to have not been formed properly, to thereby form the through-groove.

Note that the present invention is not limited to the above-described embodiments. Thus, various modifications are possible without departing from the gist of the present invention.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A laser processing apparatus comprising:
a chuck table that holds a workpiece by a holding surface;
a laser beam applying unit that applies a pulsed laser beam of such a wavelength as to be absorbed in the workpiece, to the workpiece held by the chuck table;
a processing feeding unit that moves the chuck table and the laser beam applying unit relatively to each other in a processing feeding direction;
an imaging unit that images the workpiece held by the chuck table; and
a control unit that controls at least the chuck table, the laser beam applying unit, the processing feeding unit and the imaging unit,
wherein the chuck table has:
a transparent or semi-transparent holding member that forms the holding surface; and
a light emitting body disposed on a side of a surface opposite to the holding surface of the holding member, and
the control unit includes:
an imaging instruction section that causes the imaging unit to image a processing region of the workpiece while the pulsed laser beam is being applied to the workpiece to form a through-groove in the processing region of the workpiece; and
a determination section that detects whether or not light from the light emitting body is imaged in a picked-up image obtained according to an instruction by the imaging instruction section, through the workpiece, and determines a processed state of the through-groove.

2. The laser processing apparatus according to claim 1, wherein the control unit causes application of the pulsed laser beam again to the processing region where the through-groove has been determined, by the determination section, to have not been formed properly, to thereby form the through-groove in the processing region.
